(19) United States
(12) Patent Application Publication
(10) Pub. No.: US 2025/0153273 A1
(43) Pub. Date: May 15, 2025

(54) WAFER PROCESSING APPARATUS AND WAFER PROCESSING SYSTEM INCLUDING THE SAME

(71) Applicant: Samsung Electronics Co., Ltd., Suwon-si (KR)

(72) Inventors: Da Woon LEE, Suwon-si (KR); Jae Heung LEE, Suwon-si (KR); Nam-Tae HEO, Suwon-si (KR)

(73) Assignee: Samsung Electronics Co., Ltd., Suwon-si (KR)

(21) Appl. No.: 18/650,525

(22) Filed: Apr. 30, 2024

(30) Foreign Application Priority Data
Nov. 15, 2023 (KR) 10-2023-0158059

(51) Int. Cl. B23K 26/06; B23K 26/03; B23K 26/08; B23K 26/38; B23K 101/40

(52) U.S. Cl. CPC B23K 26/0643; B23K 26/032; B23K 26/0648; B23K 26/083; B23K 26/38; B23K 2101/40

(57) ABSTRACT

A wafer processing apparatus may include a light source unit emitting a first beam, a first spatial laser modulator reflecting the first beam, a beam expander adjusting a divergence angle of the first beam, a sensor unit emitting a second beam, a second spatial laser modulator reflecting the second beam, a galvanometer reflecting the first beam or the second beam, and a condensing lens refracting the first beam or the second beam. The sensor unit may receive position information generated while the second beam is moving in a first direction on a wafer. The first beam may be condensed to a condensing point by the condensing lens. Angle information for controlling a height level of the condensing point may be generated based on the position information. The beam expander may adjust the divergence angle of the first beam based on the angle information.

### CROSS-REFERENCE TO RELATED APPLICATION

This application claims priority from Korean Patent Application No. 10-2023-0158059, filed on Nov. 15, 2023 in the Korean Intellectual Property Office and all the benefits accruing therefrom under 35 U.S.C. 119, the entire contents of which are herein incorporated by reference.

### BACKGROUND

### Technical Field

The present disclosure relates to a wafer processing apparatus and a wafer processing system including the same, and more particularly, to a wafer processing apparatus capable of efficiently using a galvanometer used for wafer processing and a wafer processing system including the same.

### Description of the Related Art

Highly scaled high integrated semiconductor chips may be spaced apart from each other at fine pitches while having fine widths on a wafer. A dicing operation may be required to divide the wafer into a plurality of semiconductor chips.

Meanwhile, the semiconductor chips should not be damaged during the dicing operation. Therefore, studies for a semiconductor processing apparatus capable of precisely cutting portions between semiconductor chips are ongoing. In addition, it is becoming important to design a semiconductor processing apparatus with improved efficiency in order to increase the production efficiency of the semiconductor chips.

### BRIEF SUMMARY

The present disclosure relates to a wafer processing apparatus that precisely cuts a wafer and/or performs a dicing process with improved efficiency.

Aspects of the present disclosure are not limited to those mentioned above and additional aspects of the present disclosure, which are not mentioned herein, will be clearly understood by those skilled in the art from the following description of the present disclosure.

According to an embodiment of the present disclosure, a wafer processing apparatus may include a light source unit configured to emit a first beam; a first spatial laser modulator configured to reflect the first beam; a beam expander configured to adjust a divergence angle of the first beam; a sensor unit configured to emit a second beam; a second spatial laser modulator configured to reflect the second beam; a galvanometer configured to reflect the first beam or the second beam; and a condensing lens configured to refract the first beam or the second beam. The sensor unit may be configured to receive position information generated while the second beam is moving in a first direction on a wafer. The condensing lens may be configured to condense the first beam to a condensing point. Angle information for controlling a height level of the condensing point may be generated based on the position information. The beam expander is configured to adjust the divergence angle of the first beam based on the angle information.

According to an embodiment of the present disclosure, a wafer processing system may include a light source unit configured to emit a first beam; a first spatial laser modulator configured to reflect the first beam emitted from the light source unit; a beam expander positioned to receive and pass through the first beam reflected by the first spatial laser modulator, the beam expander being configured to adjust a divergence angle of the first beam;

a sensor unit configured to emit a second beam; a second spatial laser modulator configured to reflect the second beam emitted from the sensor unit; a galvanometer configured to reflect the first beam after the first beam passes through the beam expander or reflect the second beam after the second beam is reflected by the second spatial laser modulator; and a condensing lens including a first surface and a second surface opposing the first surface of the condensing lens, the first surface of the condensing lens being incident to the first beam or the second beam reflected by the galvanometer, the condensing lens being configured to pass through and condense the first beam or the second beam reflected by the galvanometer; and a wafer chuck spaced apart from the second surface of the condensing lens in a first direction. In response to being reflected by the galvanometer, the first beam or the second beam may moves in a second direction towards the wafer chuck, the second direction crossing the first direction, and the wafer chuck may be configured to move in a third direction. The third direction may cross the first direction and the second direction.

According to an embodiment of the present disclosure, a wafer processing apparatus may include a light source unit configured to emit a first beam; a first shutter below the light source unit; a first spatial laser modulator below the first shutter; a beam expander spaced apart from the first spatial laser modulator; a sensor unit configured to emit a second beam;
a second shutter below the sensor unit; a second spatial laser modulator below the second shutter; a galvanometer between the second spatial laser modulator and the beam expander; and a condensing lens below the galvanometer. The second beam may be reflected towards the condensing lens by the second spatial laser modulator and the galvanometer and the second beam may pass through the condensing lens towards a wafer below the condensing lens in a first direction. The sensor unit may be configured to receive position information generated by scanning on the wafer by the second beam in a first direction. The first beam may be reflected towards the condensing lens by the first spatial laser modulator and the galvanometer. The first beam may be concentrated to a condensing point by passing through the beam expander and the condensing lens. Angle information for controlling a height level of the condensing point may be generated based on the position information, and the beam expander may be configured to adjust a divergence angle of the first beam passing through the beam expander based on the angle information.

### BRIEF DESCRIPTION OF THE DRAWINGS

FIG. 1 is a schematic perspective view illustrating a wafer processing apparatus and a wafer processing system including the same according to some embodiments of the present disclosure.

FIG. 2 is a side view illustrating a wafer processing apparatus and a wafer processing system including the same according to some embodiments of the present disclosure.

FIG. 3 is a view illustrating a beam expander included in a wafer processing apparatus and a wafer processing system including the same according to some embodiments of the present disclosure.

FIGS. 4 and 5 are views illustrating an operation of a beam expander included in a wafer processing apparatus and a wafer processing system including the same according to some embodiments of the present disclosure.

FIGS. 6 and 7 are views illustrating a beam expander included in a wafer processing apparatus and a wafer processing system including the same according to some embodiments of the present disclosure.

FIG. 8 is a view illustrating a condensing lens included in a wafer processing apparatus and a wafer processing system including the same according to some embodiments of the present disclosure.

FIG. 9 is a view illustrating a condensing lens included in a wafer processing apparatus and a wafer processing system including the same according to some embodiments of the present disclosure.

FIG. 10 is a side view illustrating a wafer processing apparatus and a wafer processing system including the same according to some embodiments of the present disclosure.

FIGS. 11 to 19 are views illustrating operations of a wafer processing apparatus and a wafer processing system including the same according to some embodiments of the present disclosure.

### DETAILED DESCRIPTION OF THE DISCLOSURE

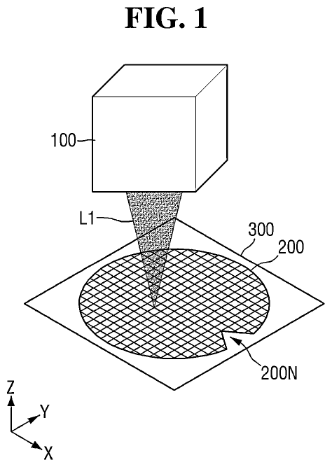

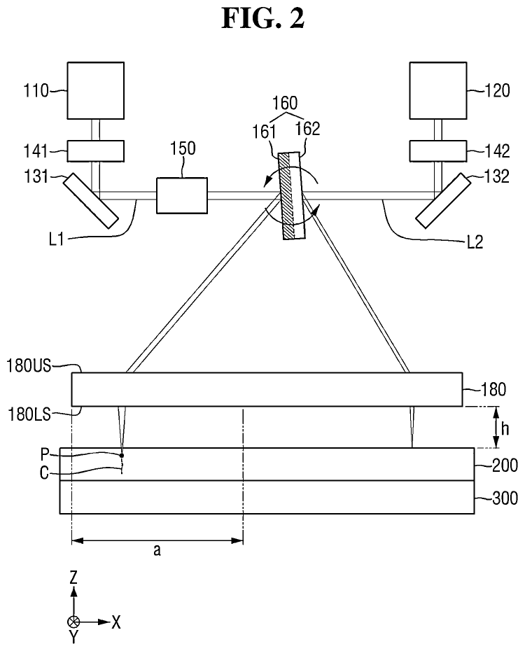

FIG. 1 is a schematic perspective view illustrating a wafer processing apparatus and a wafer processing system including the same according to some embodiments of the present disclosure. FIG. 2 is a side view illustrating a wafer processing apparatus and a wafer processing system including the same according to some embodiments of the present disclosure.

Referring to FIGS. 1 and 2, the wafer processing system may include a wafer processing apparatus 100 and a wafer chuck 300. The wafer processing apparatus 100 includes a light source unit 110, a sensor unit 120, a first spatial laser modulator 131, a second spatial laser modulator 132, a first shutter 141, a second shutter 142, a beam expander 150, a galvanometer 160, and a condensing lens 180. Although not shown, processing circuitry in the wafer processing apparatus 100 and wafer processing system may control operations of the wafer processing apparatus 100 and wafer processing system discussed below.

The light source unit 110 may generate a first beam L1. In more detail, the first beam L1 may be emitted from one surface of the light source unit 110.

Although the light source unit 110 is shown in a rectangular shape, its shape is not limited to the rectangular shape.

The light source unit 110 may include an appropriate device (e.g., laser) capable of generating the first beam L1, but is not limited thereto.

The sensor unit 120 may generate a second beam L2. In more detail, the second beam L2 may be emitted from one surface of the sensor unit 120.

Although the sensor unit 120 is shown in a rectangular shape, its shape is not limited to the rectangular shape.

The sensor unit 120 may include an appropriate device (e.g., laser) capable of generating the second beam L2, but is not limited thereto.

The first shutter 141 may be disposed below the light source unit 110. Although the first shutter 141 is shown as being disposed below the light source unit 110, the position of the first shutter 141 is not limited thereto.

The first shutter 141 may be spaced apart from the light source unit 110 in a third direction Z. The first shutter 141 is shown as being spaced apart from the light source unit 110, but is not limited thereto.

The first shutter 141 may block or open the first beam L1 emitted from the light source unit 110. When the first shutter 141 is in an open state, the first beam L1 may move along to the first spatial laser modulator 131, the beam expander 150, the galvanometer 160 and the condensing lens 180. When the first shutter 141 is in a closed state, the first beam L1 may not move along to the first spatial laser modulator 131, the beam expander 150, the galvanometer 160 and the condensing lens 180.

The first shutter 141 is shown as being disposed between the light source unit 110 and the first spatial laser modulator 131, but is not limited thereto. The first shutter 141 may be disposed at any position on a moving path of the first beam L1. For example, the first shutter 141 may be disposed between the first spatial laser modulator 131 and the beam expander 150. For another example, the first shutter 141 may be disposed between the first spatial laser modulator 131 and the galvanometer 160, such as between the beam expander 150 and the galvanometer 160.

The second shutter 142 may be disposed below the sensor unit 120. The second shutter 142 is shown as being disposed below the sensor unit 120, but is not limited thereto.

The second shutter 142 may be spaced apart from the sensor unit 120 in the third direction Z. The second shutter 142 is shown as being spaced apart from the sensor unit 120, but is not limited thereto.

The second shutter 142 may block or open the second beam L2 emitted from the sensor unit 120. When the second shutter 142 is in an open state, the second beam L2 may move along to the second spatial laser modulator 132, the galvanometer 160 and the condensing lens 180. When the second shutter 142 is in a closed state, the second beam L2 may not move along to the second spatial laser modulator 132, the galvanometer 160 and the condensing lens 180.

The second shutter 142 is shown as being disposed between the sensor unit 120 and the second spatial laser modulator 132, but is not limited thereto. The second shutter 142 may be disposed at any position on the moving path of the second beam L2. For example, the second shutter 142 may be disposed between the second spatial laser modulator 132 and the galvanometer 160.

In example embodiment, the first shutter 141 and second shutter 142 each independently may include an aperture that may be opened or closed by a motor under the control of processing circuitry (not shown) in the wafer processing apparatus 100. The first shutter 141 may include an optical block film that covers the aperture in the first shutter 141 and blocks the first beam L1 when the first shutter 141 is closed. The second shutter 142 may include an optical block film that covers the aperture in the second shutter 142 blocks the first beam L2 when the second shutter 142 is closed. Materials of the optical block films may be different in the first and second shutters 141 and 142. However, example embodiments are not limited thereto, and the first and second shutters 141 and 142 may be embodiments in different implementations.

The first spatial laser modulator (SLM) 131 may be disposed below the first shutter 141. The first spatial laser modulator 131 is shown as being disposed below the first shutter 141, but is not limited thereto.

The first spatial laser modulator 131 may be spaced apart from the first shutter 141 in the third direction Z. The first spatial laser modulator 131 is shown as being spaced apart from the first shutter 141 in the third direction Z, but is not limited thereto. For example, the first spatial laser modulator 131 may be in contact with the first shutter 141.

Although the first spatial laser modulator 131 is shown in a rectangular shape, its shape is not limited to the rectangular shape.

The first spatial laser modulator 131 may reflect the first beam L1 emitted from the light source unit 110. The first beam L1 reflected by the first spatial laser modulator 131 may be directed toward the beam expander 150. The first spatial laser modulator 131 may include a mirror for reflecting the first beam L1.

The first spatial laser modulator 131 may modulate the first beam L1. In more detail, the first spatial laser modulator 131 may adjust the intensity, phase, or wavefront of the first beam L1.

The first spatial laser modulator 131 may adjust characteristics of the first beam L1 to be suitable for characteristics required for a dicing operation. For example, the first spatial laser modulator 131 may include a liquid crystal device, a waveguide, a microelectromechanical system, and/or a combination thereof for adjusting characteristics of the first beam L1, but example embodiments are not limited thereto.

The second spatial laser modulator 132 may be disposed below the second shutter 142. The second spatial laser modulator 132 is shown as being disposed below the second shutter 142, but is not limited thereto.

The second spatial laser modulator 132 may be spaced apart from the second shutter 142 in the third direction Z. The second spatial laser modulator 132 is shown as being spaced apart from the second shutter 142 in the third direction Z, but is not limited thereto. For example, the second spatial laser modulator 132 may be in contact with the second shutter 142.

Although the second spatial laser modulator 132 is shown in a rectangular shape, its shape is not limited to the rectangular shape.

The second spatial laser modulator 132 may reflect the second beam L2 emitted from the sensor unit 120. The second beam L2 reflected by the second spatial laser modulator 132 may be directed toward the galvanometer 160. The second spatial laser modulator 133 may include a mirror for reflecting the second beam L2.

The second spatial laser modulator 132 may modulate the second beam L2. In more detail, the second spatial laser modulator 132 may adjust the intensity, phase, or wavefront of the second beam L2.

The second spatial laser modulator 132 may adjust characteristics of the second beam L2 to be suitable for characteristics required for a scanning operation. For example, the second spatial laser modulator 132 may include a liquid crystal device, a waveguide, a microelectromechanical system, and/or a combination thereof for adjusting characteristics of the second beam L2, but example embodiments are not limited thereto.

The beam expander 150 may be spaced apart from the first spatial laser modulator 131 in a first direction X. The beam expander 150 is shown as being spaced apart from the first spatial laser modulator 131 in the first direction X, but is not limited thereto.

Although the beam expander 150 is shown in a rectangular shape, its shape is not limited to the rectangular shape.

The beam expander 150 may adjust a degree of spread of the first beam L1. In more detail, a divergence angle of the first beam L1 may be adjusted by the beam expander 150.

When the divergence angle of the first beam L1 is adjusted by the beam expander 150, a height of a condensing point P on which the first beam L1 is condensed may be adjusted.

When the first beam L1 is widely spread (for example, when the divergence angle of the first beam L1 is large), a distance between the condensing lens 180 and the condensing point P may be lengthened.

When the first beam L1 is narrowly spread (for example, when the divergence angle of the first beam L1 is small), the distance between the condensing lens 180 and the condensing point P may be shortened.

When the divergence angle of the first beam L1 is appropriately adjusted, a position of the condensing point P on which the first beam L1 is condensed may be appropriately adjusted.

The beam expander 150 may be a beam expanding telescope (BET) or a tunable lens 156. The beam expander 150 may use a suitable means capable of adjusting the divergence angle of the first beam L1, and is not limited to the beam expanding telescope or the tunable lens 156.

The galvanometer 160 may be disposed between the beam expander 150 and the second spatial laser modulator 132.

The galvanometer 160 may be spaced apart from the beam expander 150 or the second spatial laser modulator 132 in the first direction X. The galvanometer 160 is shown as being spaced apart from the beam expander 150 or the second spatial laser modulator 132 in the first direction X, but is not limited thereto.

The galvanometer 160 is shown in a rectangular shape, but its shape is not limited to the rectangular shape.

The galvanometer 160 may include a reflecting mirror. The first beam L1 or the second beam L2 may be reflected through the reflecting mirror of the galvanometer 160.

The galvanometer 160 may include a first reflective surface 161 and a second reflective surface 162, which are opposite to each other.

The first reflective surface 161 may include a first reflecting mirror, and the second reflective surface 162 may include a second reflecting mirror. The reflecting characteristics of the first reflecting mirror and the reflecting characteristics of the second reflecting mirror may be different from each other. For example, a wavelength of the first beam L1 reflected by the first reflective surface 161 and a wavelength of the second beam L2 reflected by the second reflective surface 162 may be different from each other.

A moving direction of the first beam L1 or the second beam L2 may be changed by the galvanometer 160. For example, the first beam L1 reflected by the galvanometer 160 or the second beam L2 reflected by the galvanometer 160 may be directed toward the condensing lens 180.

The first beam L1 may be reflected by the first reflective surface 161. The first beam L1 reflected by the first reflective surface 161 may have a first wavelength.

The second beam L2 may be reflected by the second reflective surface 162. The second beam L2 reflected by the second reflective surface 162 may have a second wavelength.

The first wavelength and the second wavelength may be different from each other. In some embodiments, the first wavelength may be shorter than the second wavelength. Therefore, the first beam L1 reflected by the first reflective surface 161 may have sufficient energy to generate fine cracks C on a wafer 200, but the second beam L2 reflected by the second reflective surface 162 may not have sufficient energy to generate fine cracks C on the wafer 200.

The galvanometer 160 may rotate. For example, as shown in FIG. 2, the galvanometer 160 may rotate in a counterclockwise direction. The rotation direction of the galvanometer 160 may be changed depending on the position of other components without being fixed.

The galvanometer 160 may rotate around a rotary shaft. In more detail, the galvanometer 160 may rotate around a virtual axis extended in a second direction Y. The virtual axis extended in the second direction Y may pass through the galvanometer 160.

As the galvanometer 160 rotates, the first beam L1 reflected by the galvanometer 160 may move. In more detail, as the galvanometer 160 rotates in the counterclockwise direction, the first beam L1 reflected by the galvanometer 160 may move in the first direction X on the condensing lens 180. The first beam L1 reflected by the galvanometer 160 may move in the first direction X directed toward the sensor unit 120 with respect to the light source unit 110.

As the galvanometer 160 rotates, the second beam L2 reflected by the galvanometer 160 may move. In more detail, as the galvanometer 160 rotates in the counterclockwise direction, the second beam L2 reflected by the galvanometer 160 may move in the first direction X on the condensing lens 180. The second beam L2 reflected by the galvanometer 160 may move in the first direction X directed toward the sensor unit 120 based on the light source unit 110.

The first shutter 141 or the second shutter 142 may be controlled to be closed or opened depending on the degree of rotation of the galvanometer 160.

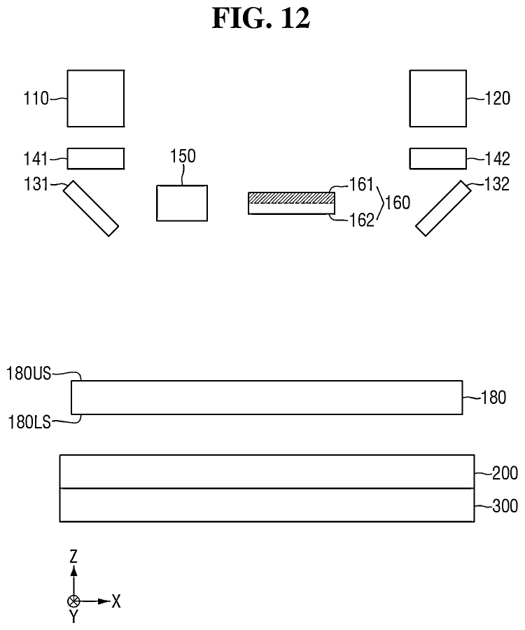

For example, when the second reflective surface 162 faces the condensing lens 180 (shown in FIG. 12), both the first shutter 141 and the second shutter 142 may be closed.

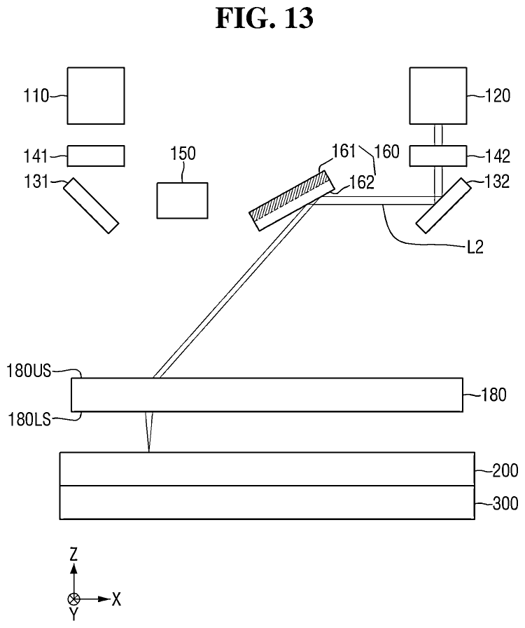

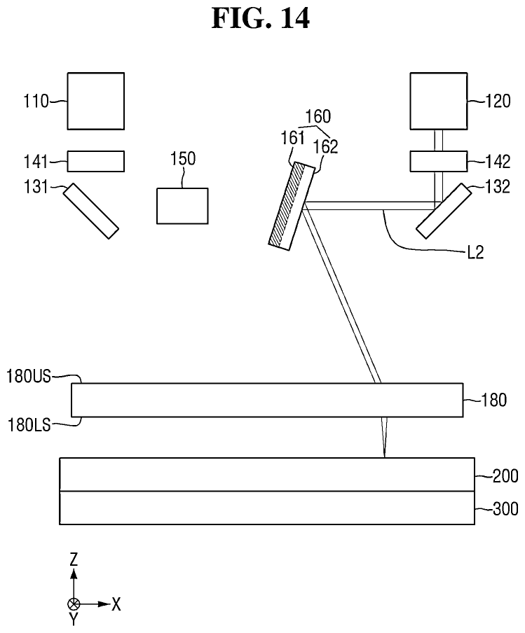

For another example, when the first reflective surface 161 is directed to face upward left and the second reflective surface 162 is directed to face downward right (shown in FIGS. 13 and 14), the first shutter 141 may be closed and the second shutter 142 may be opened.

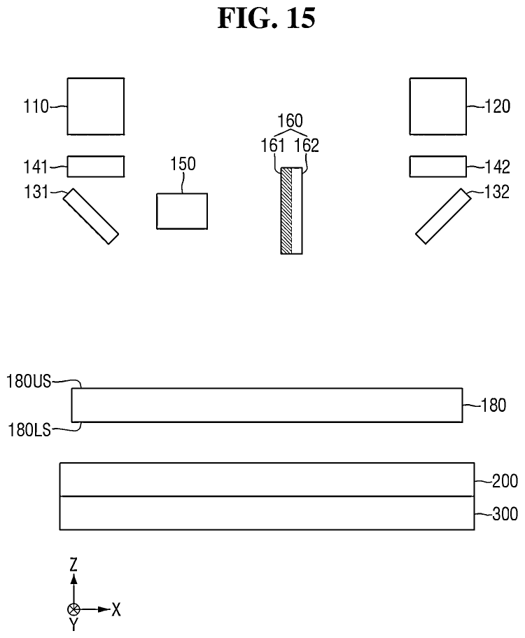

For another example, when the first reflective surface 161 faces the beam expander 150 (shown in FIG. 15), both the first shutter 141 and the second shutter 142 may be closed.

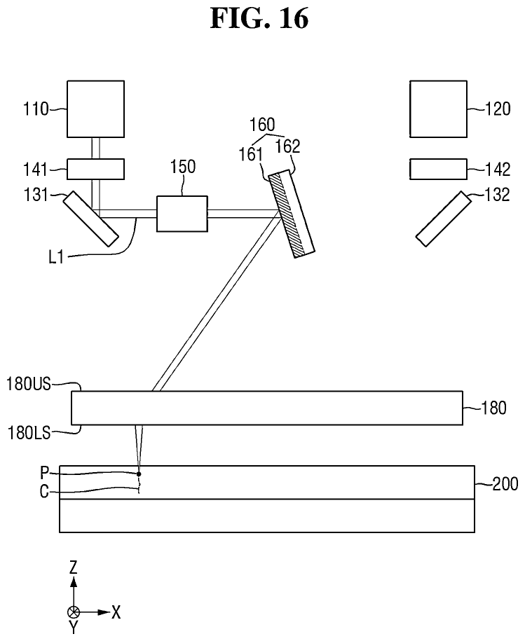

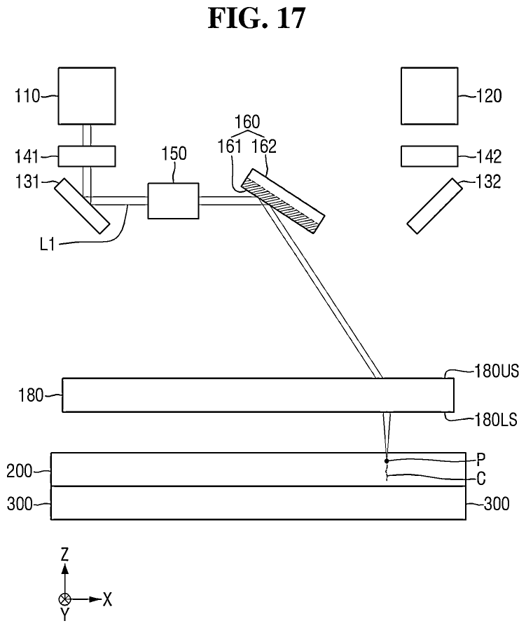

For another example, when the first reflective surface 161 is directed to face downward left and the second reflective surface 162 is directed to face upward right (shown in FIGS. 16 and 17), the first shutter 141 may be opened and the second shutter 142 may be closed.

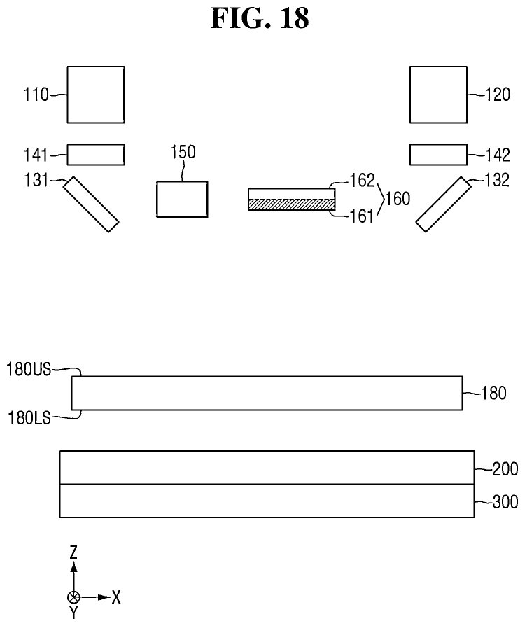

For another example, when the first reflective surface 161 faces the condensing lens 180 (shown in FIG. 18), both the first shutter 141 and the second shutter 142 may be closed.

The condensing lens 180 may be spaced apart from the galvanometer 160 in the third direction Z.

The condensing lens 180 is shown in a rectangular shape, but its shape is not limited to the rectangular shape.

The first beam L1 or the second beam L2 may pass through the condensing lens 180. The first beam L1 or the second beam L2 may be incident on a first surface 180US of the condensing lens 180. The first beam L1 or the second beam L2 may be refracted by the condensing lens 180. The first beam L1 or the second beam L2 may exit to a second surface 180LS of the condensing lens 180 opposite to the first surface in the third direction Z.

The condensing lens 180 may condense the first beam L1 reflected by the galvanometer 160 on the condensing point P.

The condensing lens 180 may allow a focal distance to be constant even though the first beam L1 or the second beam L2 is incident on the condensing lens at any incident angle. For example, even though the first beam L1 is incident on the condensing lens at any incident angle, a distance between the condensing point P and the condensing lens 180 may be uniformly maintained.

The condensing lens 180 may be a telecentric lens or a gradient index (GRIN) lens, but is not limited thereto. The condensing lens 180 may include appropriate means for uniformly maintaining the distance between the condensing point P and the condensing lens 180.

The wafer 200 may be bulk silicon or silicon-on-insulator (SOI). Otherwise, the wafer 200 may be a silicon substrate, or may include other materials such as silicon germanium, silicon germanium on insulator (SGOI), indium antimonide, lead telluride, indium arsenide, indium phosphide, gallium arsenide, or gallium antimonide. Otherwise, the wafer 200 may be an epitaxial layer formed on a base substrate.

The wafer 200 may be circular.

A plurality of semiconductor chips may be formed on the wafer 200. The plurality of semiconductor chips may be spaced apart from each other in the second direction Y based on a scribe line extended in the first direction X. The plurality of semiconductor chips may be spaced apart from each other based on a scribe line extended in the second direction Y. The wafer 200 may include a wafer notch portion 200N.

The wafer notch portion 200N may be used to indicate a crystal orientation of the wafer 200 or to align the wafer 200 during a manufacturing process. In more detail, a worker (not limited to a human) may identify the wafer 200 by identifying the wafer notch portion 200N of the wafer 200. In addition, in order to align two or more wafers 200, the worker may align the wafers 200 based on the wafer notch portion 200N of each wafer 200.

The wafer 200 may be disposed on a wafer chuck 300.

The wafer chuck 300 and the wafer 200 are shown as being in contact with each other, but are not limited thereto. For example, the wafer 200 and the wafer chuck 300 may be spaced apart from each other in the third direction Z.

The wafer chuck 300 may fix the wafer 200.

The wafer chuck 300 may move in the second direction Y.

When the wafer 200 is fixed on the wafer chuck 300, the wafer 200 may also move in the second direction Y as the wafer chuck 300 moves in the second direction Y.

Since the wafer 200 may move in the second direction Y in a state that the wafer processing apparatus 100 is fixed, the first beam L1 may pass through each scribe line only once.

The second beam L2 may scan the wafer 200 while moving in the first direction X.

When the second beam L2 scans the wafer 200, position information of the wafer 200 may be acquired.

For example, when the second beam L2 scans the wafer 200, a height ‘h’ of the condensing lens 180 may be measured based on the wafer 200. That is, a distance between the second surface 180LS of the condensing lens 180 and an upper surface of the wafer 200 may be measured.

The position information may be acquired at all points at which the wafer 200 is scanned by the second beam L2, so that position information having a continuous value may be acquired.

The sensor unit 120 may receive the position information acquired by the second beam L2 by scanning the wafer 200. Also, angle information for generating the condensing point P may be generated inside the wafer 200 based on the position information.

The beam expander 150 may adjust the divergence angle of the first beam L1 based on the angle information.

The first beam L1 may form the condensing point P inside the wafer 200 based on the adjusted divergence angle. Even though the first beam L1 moves in the first direction X due to the adjusted divergence angle, the height level of the condensing point P may be maintained at the same level.

The first beam L1 reflected from the galvanometer 160 may cut the wafer 200 in the first direction X while moving in the first direction X. In more detail, when the condensing point P is generated inside the wafer 200, a temperature near the condensing point P may be increased. Fine cracks C may be generated inside the wafer 200 due to the increased temperature near the condensing point P. Afterwards, when one surface of the wafer 200 is removed by grinding, the wafer 200 may be cut along a virtual line segment on the wafer 200 to which the first beam L1 has moved.

When the wafer processing apparatus and the wafer processing system perform a dicing process, the components of the wafer processing apparatus 100 may not move. In other words, the dicing process may be performed while only the wafer chuck 300 and the wafer 200 move.

When the wafer processing apparatus 100 moves, the angle or position of the first beam L1 or the second beam L2 may be changed due to the movement of the components of the wafer processing apparatus 100. Therefore, since the first beam L1 may deviate from the scribe line, it is likely that an error may occur in the dicing process.

In the present disclosure, the wafer processing apparatus 100 does not move, and only the wafer chuck 300 and the wafer 200 may move. Therefore, the likelihood that the first beam L1 deviates from the scribe line may be lowered. In other words, since only the wafer chuck 300 and the wafer 200 move in a state that the wafer processing apparatus 100 is fixed, the wafer 200 may be precisely cut.

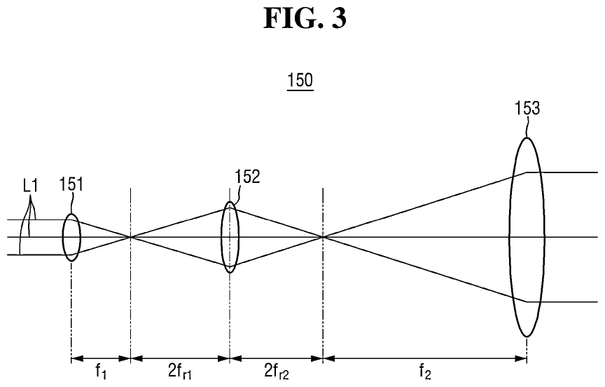

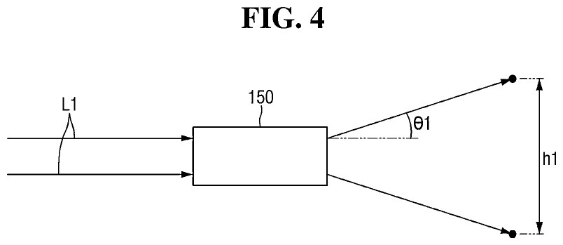

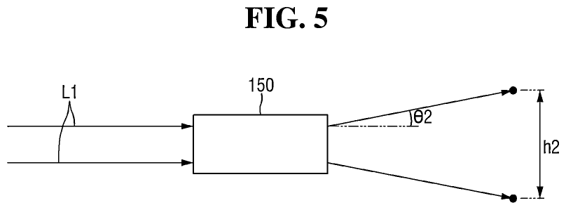

FIG. 3 is a view illustrating a beam expander included in a wafer processing apparatus and a wafer processing system including the same according to some embodiments of the present disclosure. FIGS. 4 and 5 are views illustrating an operation of a beam expander included in a wafer processing apparatus and a wafer processing system including the same according to some embodiments of the present disclosure.

Referring to FIG. 3, in some embodiments of the present disclosure, the beam expander 150 may be a beam expanding telescope.

In more detail, the beam expander 150 may include an incident lens 151, a relay lens 152, and a divergence lens 153. Each of the incident lens 151, the relay lens 152, and the divergence lens 153 may be a convex lens.

A focal distance of the incident lens 151 may be f₁.

Focal distances of the relay lens 152 may be fᵣ₁ and fᵣ₂.

A focal distance of the divergence lens 153 may be f₂.

The incident lens 151, the relay lens 152 and the divergence lens 153 may be spaced apart from one another. The relay lens 152 may be disposed between the incident lens 151 and the divergence lens 153.

As shown in FIG. 3, when a distance between the incident lens 151 and the relay lens 152 is f₁+2fᵣ₁ and a distance between the relay lens 152 and the divergence lens 153 is f₂+2fᵣ₂, the first beam L1 may pass through the divergence lens 153 while having a divergence angle of 0.

Unlike FIG. 3, when the distance between the incident lens 151 and the relay lens 152 is not f₁+2fᵣ₁ and the distance between the relay lens 152 and the divergence lens 153 is not f₂+2fᵣ₂, the first beam L1 may pass through the divergence lens 153 while having a non-zero divergence angle. In other words, when a relative position of the relay lens 152 is changed based on the incident lens 151 and the divergence lens 153, the divergence angle may be adjusted. An electric motor (not shown) may adjust the relative position of the relay lens 152 in relation to the incident lens 151 and the divergence lens 153.

Referring to FIGS. 4 and 5, when the height ‘h’ of the condensing lens 180, which is measured based on the wafer 200 shown in FIG. 1, has sizes of h1 and h2, the first beam L1 passing through the beam expander 150 have different divergence angles.

FIG. 4 shows the first beam L1 passing through the beam expander 150 when the size of ‘h’ is h1. FIG. 5 shows the first beam L1 passing through the beam expander 150 when the size of ‘h’ is h2.

A size of a first divergence angle, which is the divergence angle when the size of ‘h’ is h1, may be θ1. A size of a second divergence angle, which is the divergence angle when the size of ‘h’ is h2, may be θ2. In this case, h1 may be greater than h2.

In other words, as the size of ‘h’ is increased, the size of the divergence angle may be also increased.

When the beam expander 150 of FIG. 2 is a beam expanding telescope, the size of the divergence angle is adjusted in accordance with the size of ‘h’. Therefore, despite the change of ‘h’, the height level of the condensing point P may be uniformly maintained.

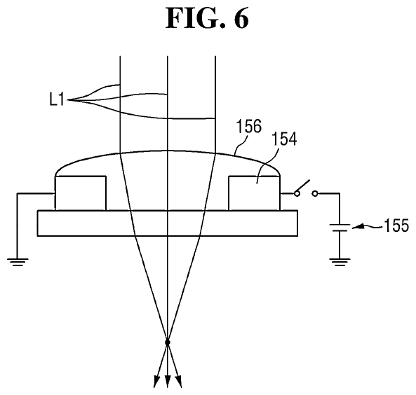

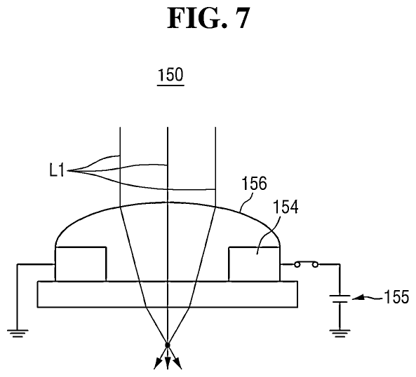

FIGS. 6 and 7 are views illustrating a beam expander included in a wafer processing apparatus and a wafer processing system including the same according to some embodiments of the present disclosure.

Referring to FIGS. 6 and 7, in some embodiments of the present disclosure, the beam expander 150 may include a tunable lens 156.

The beam expander 150 may include a temperature controller 154, a power supply unit 155, and a tunable lens 156.

The temperature controller 154 may control a temperature of the tunable lens 156.

The power supply unit 155 may supply power to the temperature controller 154.

The tunable lens 156 may be a lens of which curvature is changed depending on temperature. The tunable lens 156 may have a viscoelastic characteristic.

The tunable lens 156 may be polydimethylsiloxane (PDMS). The tunable lens 156 is not limited to PDMS, and may be any material capable of controlling a curvature by changing a desired and/or alternatively predetermined condition.

In FIG. 6, the temperature controller 154 may not be connected to the power supply unit 155. At this time, the temperature controller 154 may not receive power from the power supply unit 155. Therefore, the temperature of the temperature controller 154 may be relatively low.

Since the temperature controller 154 is in contact with the tunable lens 156, the temperature of the tunable lens 156 may be relatively low.

The tunable lens 156 may be contracted due to the relatively low temperature of the tunable lens 156. In other words, the tunable lens 156 may be relatively concave.

In FIG. 7, the temperature controller 154 may be connected to the power supply unit 155. At this time, the temperature controller 154 may be supplied with power from the power supply unit 155. Therefore, the temperature of the temperature controller 154 may be relatively high.

Since the temperature controller 154 is in contact with the tunable lens 156, the temperature of the tunable lens 156 may be relatively high.

The tunable lens 156 may expand due to the relatively high temperature of the tunable lens 156. In other words, the tunable lens 156 may be relatively convex.

Therefore, in FIGS. 6 and 7, a relatively concave degree (or a relatively convex degree) of the tunable lens 156 may be adjusted. In other words, the size of the divergence angle of the first beam L1 passing through the tunable lens 156 may be adjusted.

When the beam expander 150 of FIG. 2 includes the tunable lens 156, the size of the divergence angle is adjusted depending on the size of ‘h’. Therefore, despite the change of ‘h’, the height level of the condensing point P may be uniformly maintained.

While example have been described with reference to FIGS. 3 to 7, where the beam expander 150 may be the beam expanding telescope and the beam expander 150 may include the tunable lens 156, the structure and material of the beam expander 150 are not limited thereto. The beam expander 150 may be any means capable of adjusting the size of the divergence angle of the first beam L1.

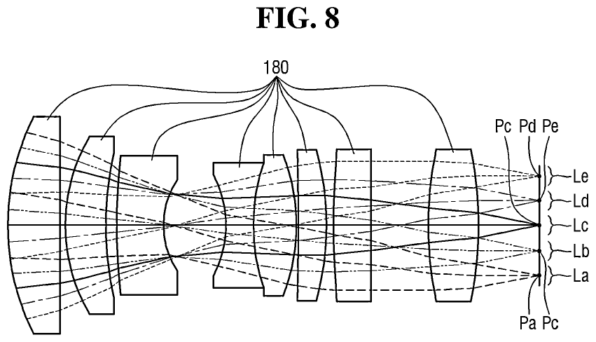

FIG. 8 is a view illustrating a condensing lens included in a wafer processing apparatus and a wafer processing system including the same according to some embodiments of the present disclosure.

Referring to FIG. 8, the condensing lens 180 may be a telecentric lens.

The same magnification may be provided regardless of the position of the beam incident on the telecentric lens.

Condensing points Pa to Pe of respective beams may be aligned in parallel regardless of the position or incident angle of the beam incident on the telecentric lens. In more detail, even though different beams La to Le are incident on the telecentric lens at different positions or at different incident angles, the condensing points Pa to Pe of the respective beams may be aligned in parallel.

When the condensing lens of FIG. 2 is a telecentric lens, distortion due to an incident angle may be corrected even though the first beam L1 incident on the condensing lens 180 has different incident angles.

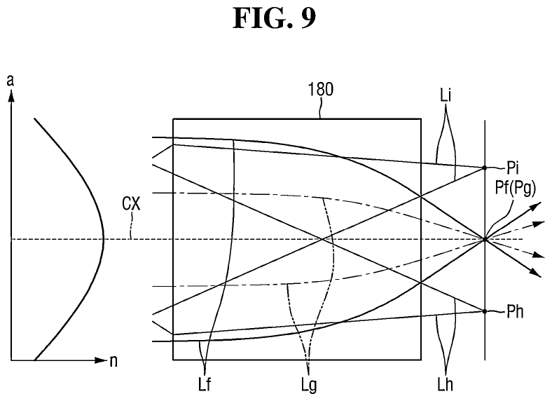

FIG. 9 is a view illustrating a condensing lens included in a wafer processing apparatus and a wafer processing system including the same according to some embodiments of the present disclosure.

Referring to FIG. 9, the condensing lens 180 may be a gradient index (GRIN) lens.

In FIG. 9, ‘a’ may be a distance in the first direction X from one sidewall of the condensing lens 180 to a specific position on the condensing lens 180 in FIG. 2.

In FIG. 9, ‘n’ may be a refractive index.

A graph may indicate a change of the value of ‘n’ according to ‘a’. A refractive index of the GRIN lens may be maximum at a center axis CX of the GRIN lens. The refractive index of the GRIN lens may be increased in a direction toward the center axis CX of the GRIN lens. The refractive index of the GRIN lens may be reduced in a direction far away from the center axis CX of the GRIN lens.

The condensing points Pf to Pi of respective beams may be aligned in parallel regardless of the position or incident angle of the beam incident on the GRIN lens. In more detail, even though different beams La to Le are incident on the GRIN lens at different positions or at different incident angles, the condensing points Pf to Pi of the respective beams may be aligned in parallel.

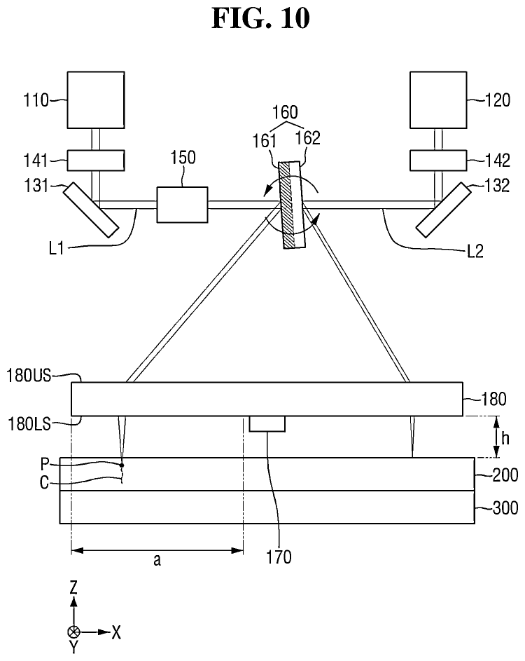

FIG. 10 is a side view illustrating a wafer processing apparatus and a wafer processing system including the same according to some embodiments of the present disclosure. For convenience of description, the following description will be based on differences from those described with reference to FIGS. 1 and 2.

Referring to FIG. 10, a wafer processing apparatus 100 according to some embodiments of the present disclosure may further include a vision camera 170.

The vision camera 170 may be protruded from the second surface 180LS of the condensing lens 180. The vision camera 170 may be disposed on the second surface 180LS of the condensing lens 180. In addition, the vision camera may be disposed between the first surface 180US and the second surface 180LS of the condensing lens 180.

Although the vision camera 170 is shown in a rectangular shape, its shape is not limited to the rectangular shape.

The vision camera 170 may identify a pattern of the wafer 200 disposed on the wafer chuck 300. In more detail, the vision camera 170 may identify whether the first beam L1 has moved along a scribe line on the wafer 200.

The vision camera 170 may limit and/or prevent the first beam L1 from moving twice or more along one scribe line by identifying the pattern of the wafer 200.

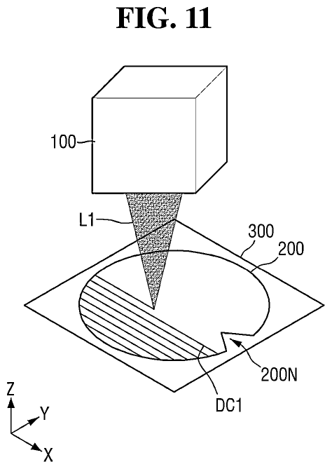

FIGS. 11 to 19 are views illustrating operations of a wafer processing apparatus and a wafer processing system including the same according to some embodiments of the present disclosure.

Referring to FIG. 11, a first dicing line DC1 may be formed. The first dicing line DC1 may be a line formed on the wafer 200 as the first beam L1 moves in the first direction X. FIG. 11 may be a view in the middle of forming the dicing line.

Referring to FIG. 11, the wafer notch portion 200N may have a shape recessed in the first direction X.

FIGS. 12 to 18 are views illustrating an operation of the wafer processing apparatus 100 for forming the first dicing line DC1 of FIG. 11.

Referring to FIG. 12, the second reflective surface 162 of the galvanometer 160 may face the condensing lens 180. The first reflective surface 161 and the second reflective surface 162 of the galvanometer 160 may be extended in the first direction X.

The first shutter 141 may block the first beam L1. The second shutter 142 may block the second beam L2.

The galvanometer 160 may rotate in a counterclockwise direction with respect to a virtual axis extended in the second direction Y.

Referring to FIG. 13, the galvanometer 160 rotates so that the first reflective surface 161 of the galvanometer 160 may be directed to face upward left and the second reflective surface 162 of the galvanometer 160 may be directed to face downward right.

The first shutter 141 may block the first beam L1. The second shutter 142 may be opened so that the second beam L2 may pass through the second shutter 142.

The second beam L2 that has passed through the second shutter 142 may be reflected by the second spatial laser modulator 132.

The second beam L2 reflected by the second spatial laser modulator 132 may be reflected by the second reflective surface 162 of the galvanometer 160.

The second beam L2 reflected by the second reflective surface 162 of the galvanometer 160 may pass through a left side of the condensing lens.

The second beam L2 that has passed through the condensing lens may scan a surface of the wafer 200.

Referring to FIG. 14, the galvanometer 160 may be further rotated in comparison with FIG. 13.

The second beam L2 may move in the first direction X.

In more detail, the second beam L2 reflected by the second reflective surface 162 of the galvanometer 160 may move to a right side of the condensing lens.

The second beam L2 that has passed through the condensing lens may scan the surface of the wafer 200 while moving in the first direction X.

As the second beam L2 scans the surface of the wafer 200 while moving the wafer 200 in the first direction X, position information may be generated.

Referring to FIG. 15, the galvanometer 160 may be further rotated in comparison with FIG. 14.

The first reflective surface 161 may face the beam expander 150. The second reflective surface 162 may face the second spatial laser modulator 132.

The first shutter 141 may block the first beam L1. The second shutter 142 may block the second beam L2.

Referring to FIG. 16, the galvanometer 160 may be further rotated in comparison with FIG. 15.

The first shutter 141 may be opened so that the first beam L1 may pass through the first shutter 141. The second shutter 142 may block the second beam L2.

The first beam L1 that has passed through the first shutter 141 may be reflected by the first spatial laser modulator 131.

The first beam L1 reflected by the first spatial laser modulator 131 may pass through the beam expander 150. The beam expander 150 may adjust the divergence angle of the first beam L1 depending on the angle information generated based on the position information.

The first beam L1 that has passed through the beam expander 150 may be reflected by the first reflective surface 161 of the galvanometer 160.

The first beam L1 reflected by the first reflective surface 161 of the galvanometer 160 may pass through the left side of the condensing lens.

The first beam L1 that has passed through the condensing lens may form a condensing point P inside the semiconductor wafer 200.

The condensing point P may form fine cracks C inside the semiconductor wafer 200.

Referring to FIG. 17, the galvanometer 160 may be further rotated in comparison with FIG. 16.

The first beam L1 may move in the first direction X.

In more detail, the first beam L1 reflected by the first reflective surface 161 of the galvanometer 160 may move to the right side of the condensing lens. The condensing point P may move to the right side of the condensing lens.

The first beam L1 that has passed through the condensing lens may continuously form fine cracks C inside the wafer 200 while moving in the first direction X.

Referring to FIG. 18, the galvanometer 160 may be further rotated in comparison with FIG. 17, and the first reflective surface 161 may face the condensing lens 180.

The first shutter 141 may block the first beam L1. The second shutter 142 may block the second beam L2.

Then, the wafer chuck 300 and the wafer 200 may move in the second direction Y in a state that the wafer processing apparatus 100 is fixed. While the wafer chuck 300 and the wafer 200 move in the second direction Y, the galvanometer 160 may rotate such that the second reflective surface 162 of the galvanometer 160 faces the condensing lens 180.

The process of moving the wafer chuck 300 and the wafer 200 in the second direction Y and the processes of FIGS. 12 to 18 may be repeated until there is no space for forming the first dicing line DC1.

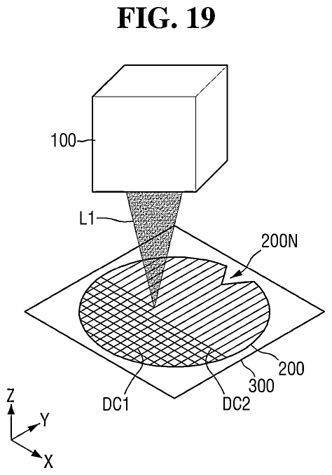

Referring to FIG. 19, the wafer chuck 300 and the wafer 200 may rotate based on a virtual axis extended in the third direction Z. The rotation angle may be 90°.

The wafer notch portion 200N may have a shape recessed in the second direction Y in accordance with the rotation of the wafer chuck 300 and the wafer 200. In addition, the first dicing line DC1 may be extended in the second direction Y.

Then, the second dicing line DC2 may be formed.

The process of moving the wafer chuck 300 and the wafer 200 in the second direction and the processes of FIGS. 12 to 18 may be repeated until there is no space for forming the second dicing line DC2.

Referring back to FIGS. 1, 11, and 19, both the first dicing line DC1 and the second dicing line DC2 may be formed, and the dicing process may be completed.

Referring back to FIGS. 12 to 18, whenever the galvanometer 160 rotates at 180°, the wafer 200 may be scanned and the dicing lines DC1 and DC2 of the wafer 200 may be formed. That is, in the present disclosure, both sides (the first reflective surface 161 and the second reflective surface 162) of the galvanometer 160, which are opposite to each other, are used so that both sides of the galvanometer 160 are not wasted.

Therefore, efficiency of a semiconductor processing process may be improved.

Also, the galvanometer 160 rotates such that the second reflective surface 162 of the galvanometer 160 faces the condensing lens 180 while the wafer chuck 300 and the wafer 200 are moving in the second direction Y. Therefore, since the dicing process may be performed immediately after the wafer chuck 300 and the wafer 200 move in the second direction Y as much as a desired and/or alternatively predetermined distance, efficiency may be improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to the presented embodiments without substantially departing from the principles of inventive concepts. Therefore, the presented embodiments are used in a generic and descriptive sense only and not for purposes of limitation.

What is claimed is:

1. A wafer processing apparatus comprising:
a light source unit configured to emit a first beam;
a first spatial laser modulator configured to reflect the first beam;
a beam expander configured to adjust a divergence angle of the first beam;
a sensor unit configured to emit a second beam;
a second spatial laser modulator configured to reflect the second beam;
a galvanometer configured to reflect the first beam or the second beam; and
a condensing lens configured to refract the first beam or the second beam, wherein
the sensor unit is configured to receive position information generated while the second beam is moving in a first direction on a wafer,
the condensing lens is configured to condense the first beam to a condensing point,
angle information for controlling a height level of the condensing point is generated based on the position information, and
the beam expander is configured to adjust the divergence angle of the first beam based on the angle information.

2. The wafer processing apparatus of claim 1, wherein
the galvanometer includes a first reflective surface and a second reflective surface, which are opposite each other,
the first reflective surface of galvanometer is configured to reflect the first beam, and
the second reflective surface of galvanometer is configured to reflect the second beam.

3. The wafer processing apparatus of claim 2, wherein the first reflective surface and the second reflective surface are configured to reflect light of different wavelengths.

4. The wafer processing apparatus of claim 1, wherein the condensing lens is configured to form the condensing point inside the wafer.

5. The wafer processing apparatus of claim 4, wherein the first beam increases a temperature of the wafer to form cracks inside the wafer.

6. The wafer processing apparatus of claim 1, wherein the galvanometer is configured to rotate based on a virtual axis extended in a second direction crossing the first direction.

7. The wafer processing apparatus of claim 6, wherein
one of the first beam or the second beam, which is reflected from the galvanometer, moves in the first direction in accordance with the rotation of the galvanometer.

8. The wafer processing apparatus of claim 6, further comprising:
a first shutter disposed on a moving path of the first beam and configured to block or open the first beam; and
a second shutter disposed on a moving path of the second beam and configured to block or open the second beam,
wherein the first shutter and the second shutter are controlled to be blocked or opened in accordance with a degree of rotation of the galvanometer.

9. The wafer processing apparatus of claim 1, wherein
the beam expander includes an incident lens, a relay lens, and a divergence lens,
the incident lens, the relay lens and the divergence lens are convex lenses,
the relay lens is between the incident lens and the divergence lens, and
the beam expander is configured to adjust the divergence angle of the first beam by adjusting a relative position of the relay lens between the incident lens and the divergence lens to change the divergence angle.

10. The wafer processing apparatus of claim 1, wherein
the beam expander includes a tunable lens, and
the beam expander is configured to adjust the divergence angle of the first beam based on changing a focal distance of the tunable lens.

11. The wafer processing apparatus of claim 1, wherein
the condensing lens is a telecentric lens, and
a magnification of the telecentric lens is constant regardless of a position of a beam incident on the telecentric lens.

12. The wafer processing apparatus of claim 1, wherein
the condensing lens is a gradient index (GRIN) lens,
a refractive index of the GRIN lens is continuously changed in accordance with a distance from a center axis of the GRIN lens, and
the refractive index of the GRIN lens is increased in a direction toward the center axis of the GRIN lens.

13. A wafer processing system comprising:
a light source unit configured to emit a first beam;
a first spatial laser modulator configured to reflect the first beam emitted from the light source unit;
a beam expander positioned to receive and pass through the first beam reflected by the first spatial laser modulator, the beam expander being configured to adjust a divergence angle of the first beam;
a sensor unit configured to emit a second beam;
a second spatial laser modulator configured to reflect the second beam emitted from the sensor unit;
a galvanometer configured to reflect the first beam after the first beam passes through the beam expander or reflect the second beam after the second beam is reflected by the second spatial laser modulator; and
a condensing lens including a first surface and a second surface opposing the first surface of the condensing lens, the first surface of the condensing lens being incident to the first beam or the second beam reflected by the galvanometer, the condensing lens being configured to pass through and condense the first beam or the second beam reflected by the galvanometer; and
a wafer chuck spaced apart from the second surface of the condensing lens in a first direction,
in response to being reflected by the galvanometer, the first beam or the second beam, moves in a second direction towards the wafer chuck, the second direction crossing the first direction, and
the wafer chuck is configured to move in a third direction, the third direction crossing the first direction and the second direction.

14. The wafer processing system of claim 13, further comprising:
a vision camera on the second surface of the condensing lens,
wherein the vision camera is configured to identify a pattern of the wafer on the wafer chuck.

15. The wafer processing system of claim 13, wherein the wafer chuck is configured to rotate based on a virtual axis extending in the first direction.

16. The wafer processing system of claim 13, wherein
the galvanometer includes a first reflective surface and a second reflective surface, which are opposite each other,
the first surface of galvanometer is configured to reflect the first beam, and
the second surface of galvanometer is configured to reflect the second beam.

17. The wafer processing system of claim 13, wherein the galvanometer is configured to rotate based on a virtual axis extending in the third direction.

18. The wafer processing system of claim 17, wherein
in response to being reflected by the galvanometer, the first beam or the second beam moves in the second direction in accordance with the rotation of the galvanometer.

19. The wafer processing system of claim 13, wherein
the condensing lens is configured to pass through and condense the first beam or the second beam to a condensing point, and
the condensing point is between the condensing lens and the wafer chuck.

20. A wafer processing apparatus comprising:
a light source unit configured to emit a first beam;
a first shutter below the light source unit;
a first spatial laser modulator below the first shutter;
a beam expander spaced apart from the first spatial laser modulator;
a sensor unit configured to emit a second beam;
a second shutter below the sensor unit;
a second spatial laser modulator below the second shutter;
a galvanometer between the second spatial laser modulator and the beam expander; and
a condensing lens below the galvanometer, wherein
the second beam is reflected towards the condensing lens by the second spatial laser modulator and the galvanometer and the second beam passes through the condensing lens towards a wafer below the condensing lens in a first direction, the sensor unit is configured to receive position information generated by scanning on the wafer by the second beam in a first direction,
the first beam is reflected towards the condensing lens by the first spatial laser modulator and the galvanometer and is concentrated to a condensing point by passing through the beam expander and the condensing lens,
angle information for controlling a height level of the condensing point is generated based on the position information, and
the beam expander is configured to adjust a divergence angle of the first beam passing through the beam expander based on the angle information.
